(19) United States
(12) Patent Application Publication
(10) Pub. No.: US 2009/0316936 A1
(43) Pub. Date: Dec. 24, 2009

(54) Pulse detection apparatus, method for manufacturing the same and connector unit

(75) Inventors: Satoshi Sakurai, Shinagawa (JP); Ayumu Akabane, Shinagawa (JP); Takashi Arita, Shinagawa (JP)

Correspondence Address: STAAS & HALSEY LLP, SUITE 700, 1201 NEW YORK AVENUE, N.W., WASHINGTON, DC, 20005, US

(73) Assignee: FUJITSU COMPONENT LIMITED, Tokyo (JP)

(21) Appl. No.: 12/457,761

(22) Filed: Jun. 19, 2009

(30) Foreign Application Priority Data
Jun. 20, 2008 (JP) 2008-162393

(51) Int. Cl. H04R 3/00; H05K 13/00

(52) U.S. Cl. 381/111; 29/592.1

(57) ABSTRACT

A pulse detection apparatus including: a connector unit capable of connecting earphones; a first cable that is joined to the connector unit, and connected to a portable device; a second cable that connects the portable device and a pulse sensor to each other; and a cover portion that covers the connector unit such that the earphones are connectable to the connector unit, and covers the second cable such that the second cable passes through the inside of the cover portion.

### BACKGROUND OF THE INVENTION

1. Field of the Invention

The present invention relates to a pulse detection apparatus, a method for manufacturing the pulse detection apparatus, and a connector unit, and more particularly to the pulse detection apparatus to which earphones are connectable, a method for manufacturing the pulse detection apparatus, and a connector unit.

2. Description of the Related Art

A pulse detection apparatus used for acquiring pulse information relating to a user's pulse acquires the pulse information by putting a pulse sensor on an auricle, for example. The acquired pulse information is processed with a portable device, and stored into the portable device. Japanese Patent Publication No. 2005-185725 discloses an apparatus having the pulse detection apparatus and the earphones.

In Japanese Patent Publication No. 2005-185725, a user can confirm measured pulse data by sound. Also, the user can listen to a radio sound or the like with a pronunciation unit.

However, the earphones, the pulse sensor, and the portable device are combined with each other, and hence the user must put on the earphones even when the earphones are unnecessary. In addition, the user must put on the portable device behind the user's head. Consequently, a pulse detection apparatus can be envisaged in which the earphones are detachable, and a connection line between the portable device and the pulse sensor is provided. However, the manufacturing process of the pulse detection apparatus becomes complex.

### SUMMARY OF THE INVENTION

It is an object of the present invention to provide a pulse detection apparatus, a method for manufacturing the pulse detection apparatus, and a connector unit that can be easily manufactured.

According to an aspect of the present invention, there is provided a pulse detection apparatus including: a connector unit capable of connecting earphones; a first cable that is joined to the connector unit, and connected to a portable device; a second cable that connects the portable device and a pulse sensor to each other; and a cover portion that covers the connector unit such that the earphones are connectable to the connector unit, and covers the second cable such that the second cable passes through the inside of the cover portion.

With the above arrangement, it is possible to provide a user with the pulse detection apparatus that can be easily manufactured.

### BRIEF DESCRIPTION OF THE DRAWINGS

Preferred embodiments of the present invention will be described in detail with reference to the following drawings, wherein:

FIG. 1 is a block diagram showing a pulse detection apparatus according to a first embodiment of the present invention;

FIG. 2 is a diagram showing the appearance of the pulse detection apparatus according to the first embodiment of the present invention;

FIG. 3 is a perspective view showing an earphone connection unit;

FIG. 4 is an exploded perspective view showing the earphone connection unit according to a comparative example;

FIG. 5 is a diagram showing a cable according to the first embodiment of the present invention;

FIG. 6 is an exploded perspective view showing the earphone connection unit according to the first embodiment of the present invention;

FIG. 7A is a rear view of a connector unit;

FIG. 7B is an enlarged view of a lead;

FIG. 8A is a rear view of a connector unit according to a second embodiment of the present invention;

FIG. 8B is an enlarged view of leads;

FIG. 9A is a rear view of a connector Unit according to a variation example of the second embodiment; and

FIG. 9B is an enlarged view of leads.

### DESCRIPTION OF THE PREFERRED EMBODIMENTS

A description will now be given, with reference to the accompanying drawings, of an embodiment of the present invention.

### First Embodiment

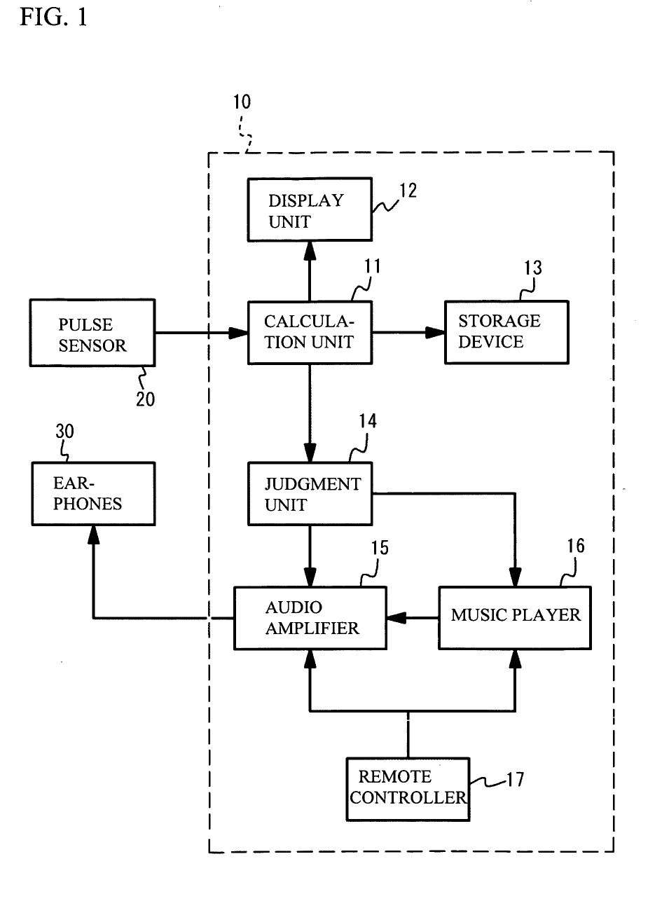

FIG. 1 is a block diagram showing a pulse detection apparatus according to a first embodiment of the present invention. The pulse detection apparatus includes a portable device 10, a pulse sensor 20, and earphones 30. Pulse waves detected by the pulse sensor 20 are output to a calculation unit 11. The calculation unit 11 is composed of a CPU, for example, calculates pulse information relating to pulses, and outputs the result of the calculation to a display unit 12. The display unit 12 is composed of a liquid crystal display unit, for example, and displays the result of the calculation. The result of the calculation indicates the number of pulses calculated from the pulse waves, for example. A storage device 13 is composed of a nonvolatile memory, for example, and stores pulse biological information including the pulse information, the result of the calculation, or the like. The calculation unit 11 outputs the result of the calculation to a judgment unit 14.

The judgment unit 14 judges a user's living body situation (e.g. a relaxation state and a tension state) based on the result of the calculation. The judgment unit 14 controls an audio amplifier 15 and a music player 16 based on the result of the judgment. The music player 16 may be composed of a radio receiver, a portable game player, a portable phone, or the like, other than the exclusive music player. The audio amplifier 15 amplifies sound output from the music player 16, and outputs the amplified sound to the earphones 30. A remote controller 17 is used to perform the operation of a volume of the audio amplifier 15 and the operation (e.g. selection of music) of the music player 16. When the number of pulses of the user is settled down, for example, the judgment unit 14 judges that the user's living body situation is in the relaxation state. Then, the judgment unit 14 causes the music player 16 to select a music with a slow tempo, and causes the audio amplifier 15 to lower the volume thereof.

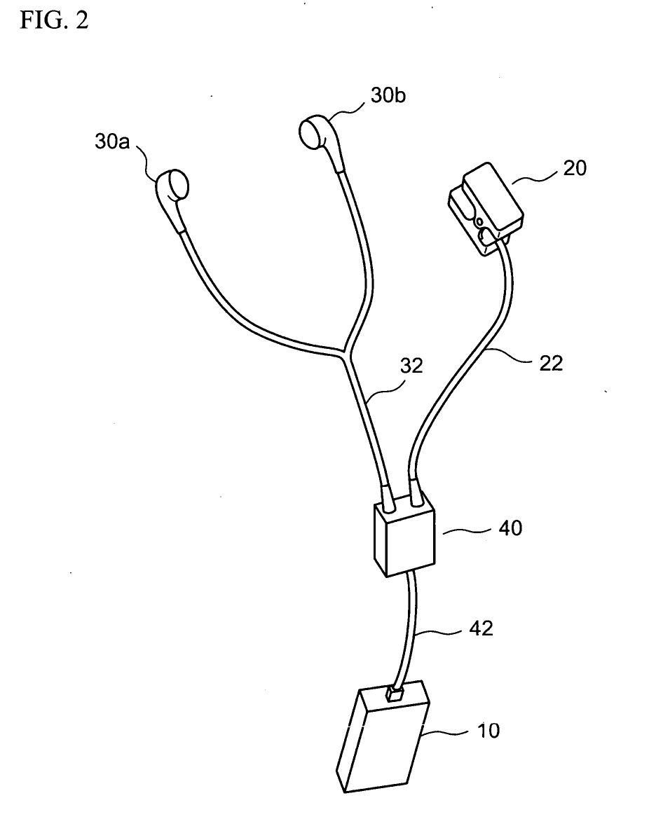

FIG. 2 is a diagram showing the appearance of the pulse detection apparatus according to the first embodiment of the present invention. The pulse sensor 20 is connected to the portable device 10 via a first cable 42 and a second cable 22. An earphone connection unit 40 is provided between the first cable 42 and the second cable 22. The earphones 30a and 30b are connected to the portable device 10 via a third cable 32, the earphone connection unit 40, and the first cable 42. The portable device 10 is attached to a belt for the waist and a pocket of a jacket, for example. The earphones 30a and 30b are inserted into external auditory canals. The pulse sensor 20 is put on an ear, for example.

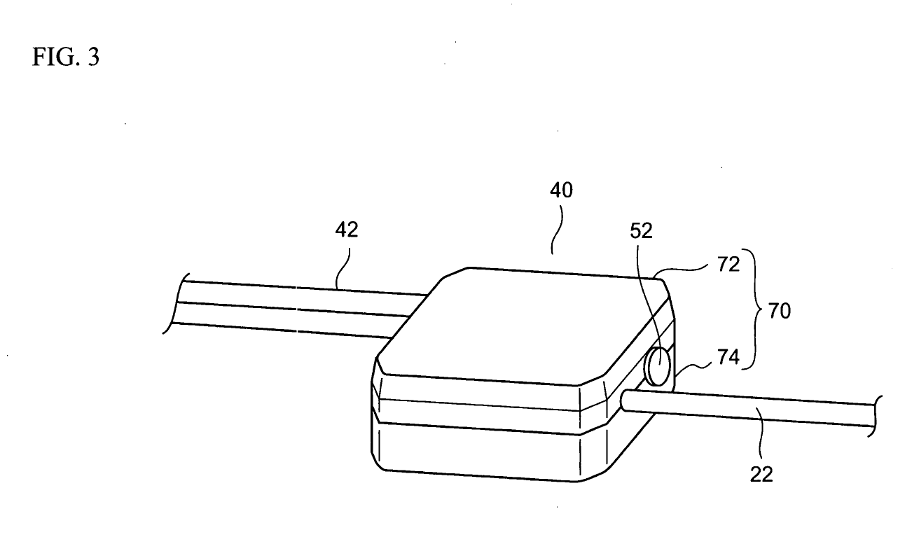

FIG. 3 is a perspective view showing the earphone connection unit. The earphone connection unit 40 is covered with a cover unit 70. The cover unit 70 includes a lower cover 74 and an upper cover 72, and is formed such that the lower cover 74 engages with the upper cover 72. A jack-type connector unit 52 of a connector unit 50 that can connect the earphones is exposed from the cover unit 70. The second cable 22 connected with the pulse sensor 20 and the first cable 42 connected with the portable device 10 are extended from the cover unit 70.

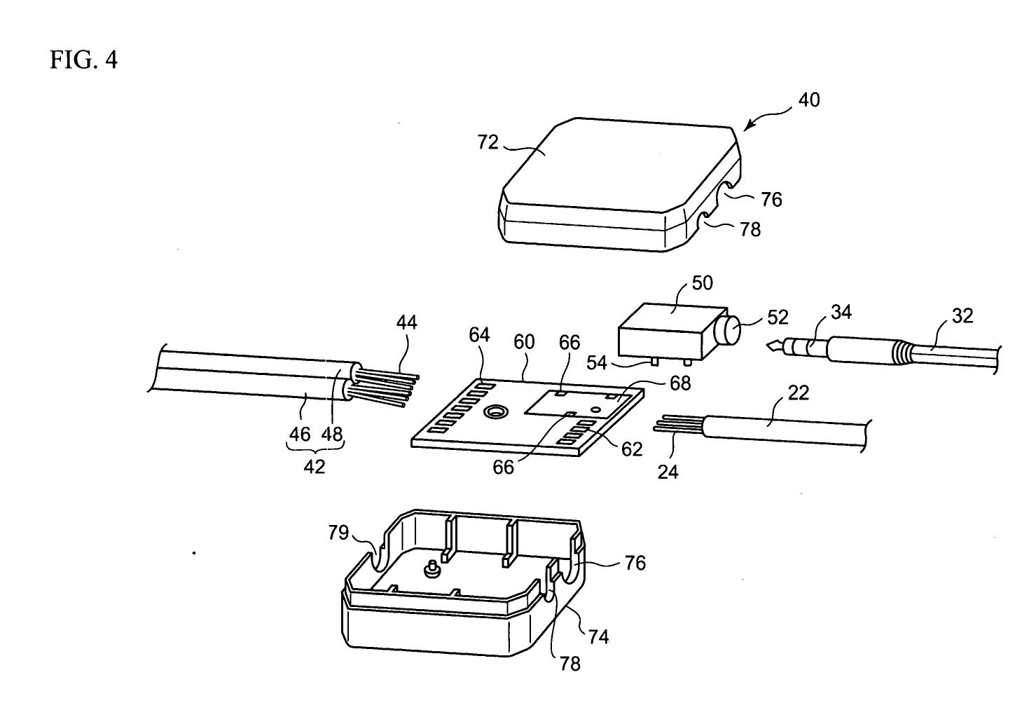

FIG. 4 is an exploded perspective view showing the earphone connection unit 40 according to a comparative example which is the same as the first embodiment in the appearance thereof. A printed-circuit board 60 is provided in the cover unit 70. Electrodes 62 to 66 are formed on an upper surface of the printed-circuit board 60. The connector unit 50 is fixed at a connector unit fixed area 68 in the upper surface of the printed-circuit board 60. A lead 54 of the connector unit 50 is electrically connected to the electrode 66 with solder or the like. The first cable 42 connected with the portable device 10 includes a cable 48 to be connected with the earphones 30a and 30b, and a cable 46 to be connected with the pulse sensor 20. The cables 46 and 48 are integrated, to thereby form the single cable 42. Conductive lines 44 in the first cable 42 are soldered with the electrode 64. Conductive lines 24 in the second cable 42 connected with the pulse sensor 20 are soldered with the electrode 62. Thereby, the cable 46 in the first cable 42 is electrically connected to the second cable 22. The cable 48 in the first cable 42 is electrically connected to the connector unit 50. An earphone pin-type connector 34 of the third cable 32 connected with the earphones 30a and 30b can be inserted into the jack-type connector unit 52 of the connector unit 50. Cutouts 76, 78, and 79 are formed on both of the upper cover 72 and the lower cover 74. By the cutouts 76, the jack-type connector unit 52 is exposed from the cover unit 70. By the cutouts 78 and 79, the second cable 22 and the first cable are extended from the cover unit 70.

According to the comparative example of FIG. 4, the earphones 30a and 30b are detachable to the jack-type connector unit 52 in the earphone connection unit 40. Therefore, when the earphones 30a and 30b are attached to the jack-type connector unit 52, the earphones 30a and 30b can be detached. Also, the portable device 10 and the pulse sensor 20 are connected to each other with the cables 42 and 22, so that the portable device 10 can be attached at a position away from a user's head, such as the pocket and the belt. In addition, the earphone connection unit 40 is provided in the pulse detection apparatus, so that the single first cable 42 can be connected between the portable device 10 and the earphone connection unit 40, and the branching of the earphones 30 (30a and 30b) and the pulse sensor 20 put on the ear can be done in the vicinity of the user's head. As a result, the number of cables can be reduced.

However, in the comparative example of FIG. 4, the first cable 42 and the second cable 22 are connected to the printed-circuit board 60 with the solder, and hence the manufacturing process of the earphone connection unit 40 becomes complex. The earphone connection unit 40 in which the manufacturing thereof is easy is offered by the first embodiment explained hereinafter.

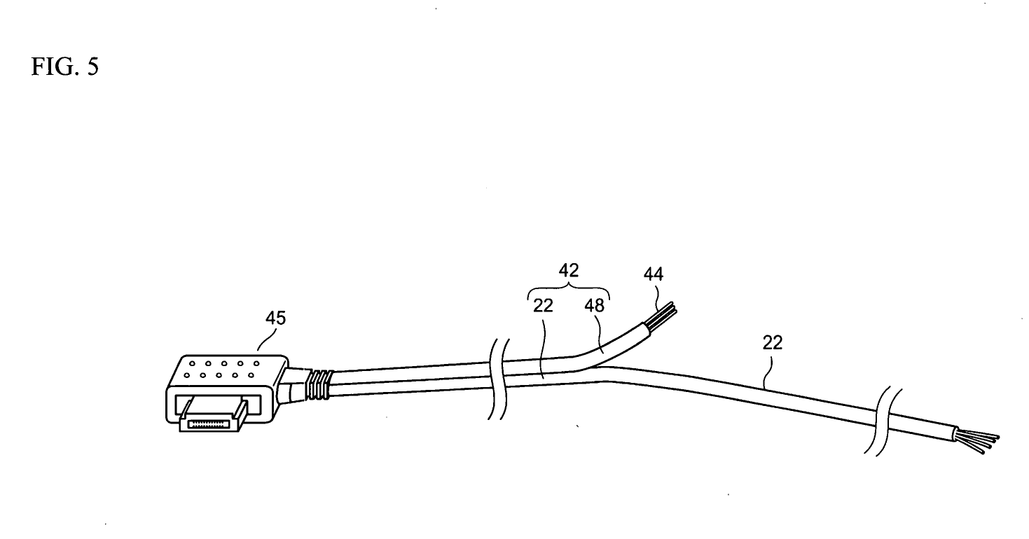

FIG. 5 is a diagram showing the appearance of the first cable 42 and the second cable 22 according to the first embodiment. Referring to FIG. 5, a connector 45 connected with the portable device 10 is provided at a tip of the first cable 42. A cable 22, included in the first cable 42, to be connected with the pulse sensor 20 is directly connected to the second cable 22. That is, the second cable 22 is formed so as to be connected between the portable device 10 and the pulse sensor, without being cut therebetween.

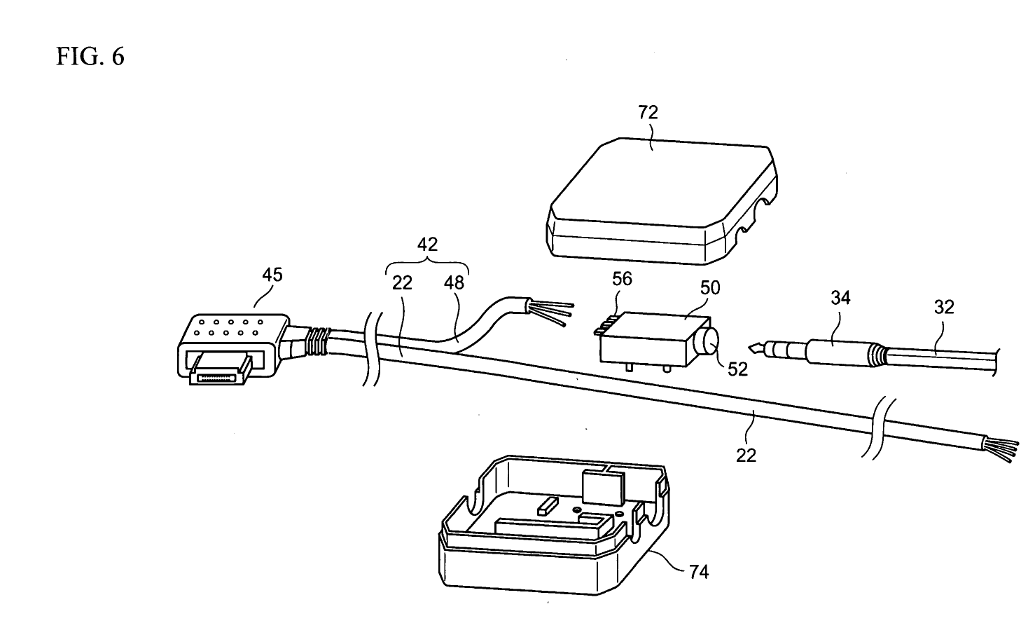

FIG. 6 is an exploded perspective view showing the earphone connection unit 40 according to the first embodiment. The printed-circuit board is not provided in the earphone connection unit 40. The cable 48, included in the first cable 42, to be connected between the earphones 30 and the portable device 10 is joined to leads 56 provided on the connector unit 50, with the solder. The lower cover 74 engages with the upper cover 72, so that the cover unit 70 is formed. The cover unit 70 covers the connector unit 50 such that the earphones 30 can be connected to the connector unit 50. Also, the cover unit 70 covers the second cable 22 such that the second cable 22 connected between the pulse sensor 20 and the portable device 10 passes through the inside of the cover unit 70.

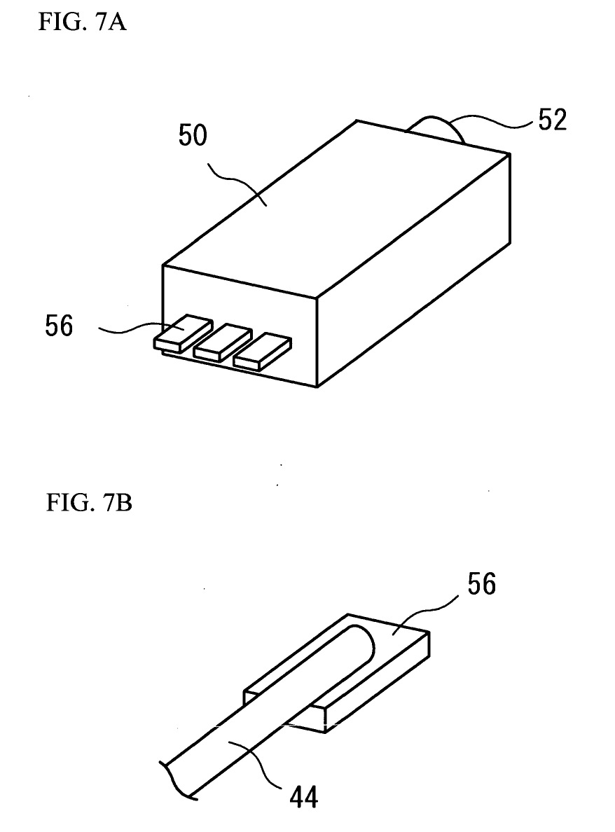

FIG. 7A is a rear view of the connector unit according to the first embodiment, and FIG. 7B is an enlarged view of the lead and a conductive line. Referring to FIG. 7A, the jack-type connector unit 52 which can connect the cable is provided on a front face of the connector unit 50, and the lead 56 which is electrically connected to the jack-type connector unit 52 and is joined to other cable with the solder is provided on a rear face of the connector unit 50. Referring to FIG. 7B, a conductive line 44 of the cable 48 is arranged on the lead 56, and soldered.

According to the first embodiment, the cable 48 included in the first cable 42 is joined to the connector unit 50 with the solder as shown in FIGS. 7A and 7B, and the cover unit 70 covers the second cable 22 such that the second cable 22 passes through the inside of the cover unit 70, as shown in FIG. 6. Therefore, it is possible to omit soldering the printed-circuit board needed in the comparative example of FIG. 4, and the manufacturing of the earphone connection unit 40 becomes easy. Since the printed-circuit board is not used, the cost can be reduced.

In the first embodiment, the lower cover 74 that consists of a resin such as an ABS resin engages with the upper cover 72 that consists of the same resin, so that the cover unit 70 is formed. Therefore, the cover unit 70 can be easily formed. The connector unit 50 to which the cable 48 is connected, and the second cable 22 are previously disposed on the lower cover 74, and the lower cover 74 and the upper cover 72 (i.e., the cover unit 70) may be integrally molded with the resin. Also, a metal material may cover the cover unit 70, thereby reducing a noise.

### Second Embodiment

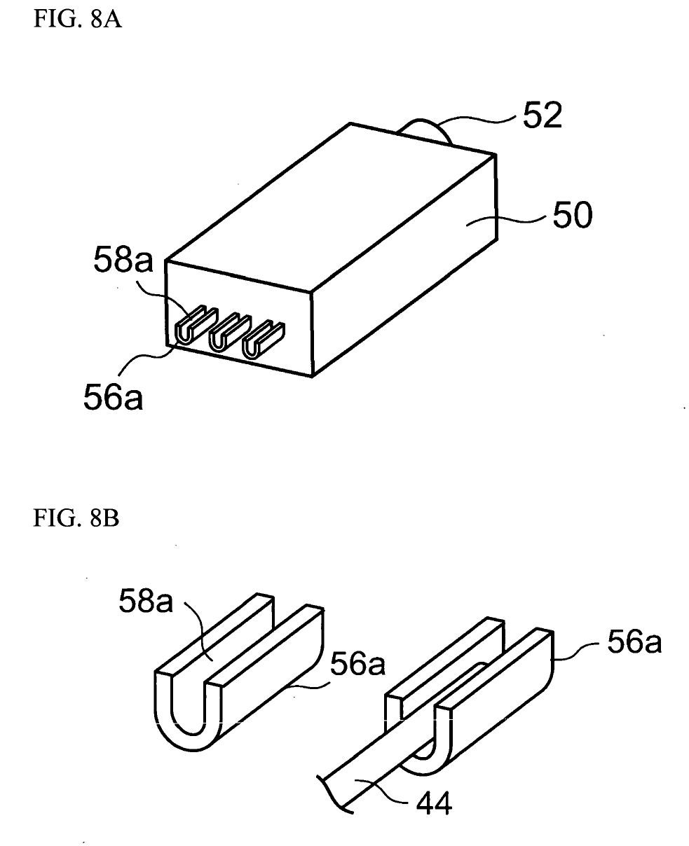

The second embodiment indicates other example of the connector unit. FIG. 8A is a rear view of the connector unit according to the second embodiment of the present invention, and FIG. 8B is an enlarged view of leads and a conductive line. Referring to FIGS. 8A and 8B, each lead 56a includes a concave part 58a. The conductive line 44 of the first cable 42 is joined to the concave part 58a of the lead 56a with the solder. Thereby, the intensity of the solder-joined part can be increased.

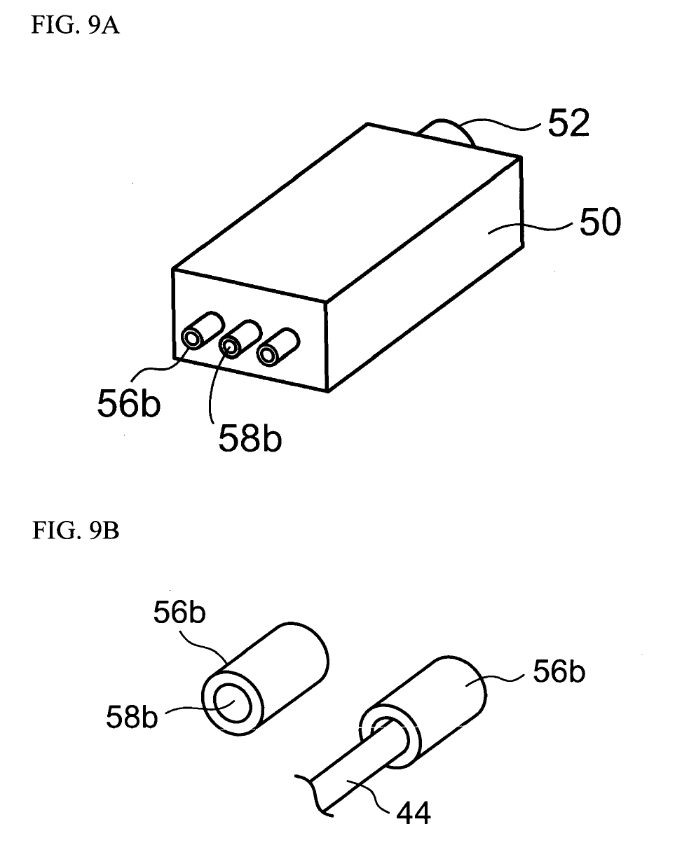

FIG. 9A is a rear view of the connector unit according to a variation example of the second embodiment, and FIG. 9B is an enlarged view of leads and a conductive line. Referring to FIGS. 9A and 9B, each lead 56b includes a hole part 58b. The conductive line 44 of the first cable 42 is inserted into the hole part 58b of the lead 56b, and joined to the hole part 58b with the solder. Thereby, the intensity of the solder joined part can be increased.

It should be noted that the present invention is not limited to the embodiments, and various modifications may be made to them without departing from the scope of the invention.

The Present application is based on Japanese Patent Application No. 2008-162393 filed Jun. 20, 2008, the entire disclosure of which is hereby incorporated by reference.

What is claimed is:

1. A pulse detection apparatus comprising:
a connector unit capable of connecting earphones;
a first cable that is joined to the connector unit, and connected to a portable device;
a second cable that connects the portable device and a pulse sensor to each other; and
a cover portion that covers the connector unit such that the earphones are connectable to the connector unit, and covers the second cable such that the second cable passes through the inside of the cover portion.

2. The pulse detection apparatus as claimed in claim 1, wherein the cover portion has an upper cover and a lower cover, and the cover portion is formed such that the lower cover engages with the upper cover.

3. The pulse detection apparatus as claimed in claim 1, wherein the connector unit includes a connector portion capable of connecting the earphones, and a lead that is electrically connected to the connector portion and joined to the second cable with solder.

4. The pulse detection apparatus as claimed in claim 3, wherein the lead includes a concave portion, and the first cable is joined to the concave portion of the lead with the solder.

5. The pulse detection apparatus as claimed in claim 3, wherein the lead includes a hole portion, and the first cable is inserted into the hole portion of the lead and joined to the hole portion with the solder.

6. A method for manufacturing a pulse detection apparatus, comprising:
joining a first cable to be connected to a portable device, to a connector unit capable of connecting earphones; and
forming a cover portion that covers the connector unit such that the earphones are connectable to the connector unit, and covers a second cable connecting the portable device and a pulse sensor to each other such that the second cable passes through the inside of the cover portion.

7. A connector unit comprising:
a connector portion capable of connecting a cable; and
a lead that is electrically connected to the connector portion, and includes a concave portion or a hole portion to be joined to other cable with solder.
